(19) United States
(12) Patent Application Publication
(10) Pub. No.: US 2024/0332228 A1
(43) Pub. Date: Oct. 3, 2024

(54) SEMICONDUCTOR DEVICES HAVING UPPER CONDUCTIVE PATTERNS AND SEMICONDUCTOR PACKAGES HAVING THE SAME

(71) Applicant: Samsung Electronics Co., Ltd., Suwon-si (KR)

(72) Inventors: Joongwon SHIN, Suwon-si (KR); Yeonjin LEE, Suwon-si (KR); Jongmin LEE, Suwon-si (KR); Jimin CHOI, Suwon-si (KR)

(73) Assignee: Samsung Electronics Co., Ltd., Suwon-si (KR)

(21) Appl. No.: 18/535,351

(22) Filed: Dec. 11, 2023

(30) Foreign Application Priority Data
Mar. 28, 2023 (KR) 10-2023-0040295

(51) Int. Cl. H01L 23/00; H01L 23/31; H01L 23/48; H01L 23/522; H01L 25/065

(52) U.S. Cl. CPC H01L 24/05; H01L 23/3107; H01L 23/481; H01L 23/5226; H01L 24/16; H01L 25/0657; H01L 2224/02206; H01L 2224/05016; H01L 2224/05124; H01L 2224/05166; H01L 2224/05181; H01L 2224/05184; H01L 2224/16145

(57) ABSTRACT

A semiconductor device includes an insulating structure on a semiconductor substrate, lower conductive patterns in the insulating structure, upper conductive patterns on the insulating structure, conductive vias in the insulating structure and connecting at least one of the upper conductive patterns to at least one of the lower conductive patterns, a protective layer covering the insulating structure and the upper conductive patterns, an etch stop layer covering the protective layer, a first passivation layer on portions of the etch stop layer between the upper conductive patterns, and an upper passivation layer on the first passivation layer.

### CROSS-REFERENCE TO RELATED APPLICATION(S)

This application claims benefit of priority to Korean Patent Application No. 10-2023-0040295 filed on Mar. 28, 2023 in the Korean Intellectual Property Office, the disclosure of which is incorporated herein by reference in its entirety.

### BACKGROUND

The present inventive concepts relate to semiconductor devices having an upper conductive pattern, and/or semiconductor packages including the same.

As demands for high performance, high speed, and/or multifunctionality of semiconductor devices increase, a degree of integration of semiconductor devices is increasing. In manufacturing a semiconductor device with a fine pattern corresponding to the trend of high integration of semiconductor devices, it is necessary to implement patterns having a fine width or a fine separation distance. In addition, a high degree of integration of semiconductor devices mounted in a semiconductor package is required.

### SUMMARY

Some example embodiments of the present inventive concepts provide semiconductor packages having a miniaturized test pad.

According to an example embodiment of the present inventive concepts, a semiconductor device includes an insulating structure on a semiconductor substrate, lower conductive patterns in the insulating structure, upper conductive patterns on the insulating structure, conductive vias in the insulating structure and connecting at least one of the upper conductive patterns to at least one of the lower conductive patterns, a protective layer covering the insulating structure and the upper conductive patterns, an etch stop layer covering the protective layer, a first passivation layer between the upper conductive patterns and on the etch stop layer, and an upper passivation layer on the first passivation layer.

According to an example embodiment of the present inventive concepts, a semiconductor package includes a plurality of semiconductor devices sequentially stacked on a buffer chip, an adhesive layer between the plurality of semiconductor devices, and an encapsulant covering the buffer chip and the plurality of semiconductor devices, wherein each of the semiconductor devices includes a semiconductor substrate, an insulating structure on an upper surface of the semiconductor substrate, a via pad on a lower surface of the semiconductor substrate, a through-electrode connected to the via pad and passing through the semiconductor substrate, upper conductive patterns on the insulating structure, a protective layer covering the insulating structure and the upper conductive patterns, an etch stop layer covering the protective layer, a first passivation layer between the upper conductive patterns and on the etch stop layer, an upper passivation layer on the first passivation layer, and a connection pad connected to one of the upper conductive patterns.

According to an example embodiment of the present inventive concepts, a semiconductor device includes a semiconductor substrate including a device region, an edge region surrounding the device region, and a cutting region surrounding the edge region, an insulating structure on the semiconductor substrate, the insulating structure including a first upper insulating layer, a second upper insulating layer, and a third upper insulating layer that are sequentially stacked, lower conductive patterns in the first upper insulating layer, a first upper conductive pattern and a second upper conductive pattern on the insulating structure, conductive vias passing through the second upper insulating layer and the third upper insulating layer, the conductive vias connecting the first upper conductive pattern to at least one of the lower conductive patterns, and a passivation structure on the insulating structure, the first upper conductive pattern, and the second upper conductive pattern, the passivation structure including an opening exposing the first upper conductive pattern, wherein the passivation structure includes a protective layer covering the first upper conductive pattern and the second upper conductive pattern, an etch stop layer covering the protective layer, a first passivation layer between the first upper conductive pattern and the second upper conductive pattern and on the etch stop layer, a second passivation layer covering the etch stop layer and the first passivation layer, and an upper passivation layer on the second passivation layer.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view of a semiconductor substrate including a semiconductor device according to an example embodiment.

FIG. 2 is a partially enlarged view of FIG. 1.

FIGS. 3 to 11 are vertical cross-sectional views along the line I-I′ of FIG. 2 of a semiconductor substrate illustrating a process sequence of a method of manufacturing a semiconductor device according to an example embodiment.

FIG. 12 is a partially enlarged view of the semiconductor device of FIG. 11.

FIG. 13 is a plan view of a semiconductor device according to an example embodiment.

FIGS. 14 to 18 are vertical cross-sectional views of a semiconductor device according to some example embodiments.

FIG. 19 is a vertical cross-sectional view of a semiconductor device according to an example embodiment.

FIG. 20 is a vertical cross-sectional view of a semiconductor package including a semiconductor device according to some example embodiments.

FIG. 21 is a partially enlarged view of the semiconductor package of FIG. 20.

FIG. 22 is a vertical cross-sectional view of a semiconductor package including a semiconductor device according to some example embodiments.

### DETAILED DESCRIPTION

Hereinafter, with reference to the accompanying drawings, some example embodiments will be described as follows.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

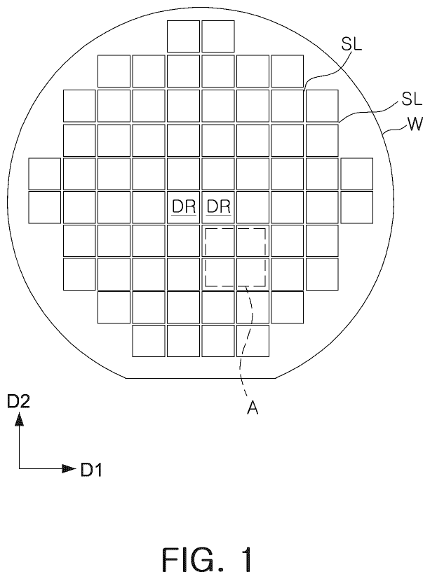

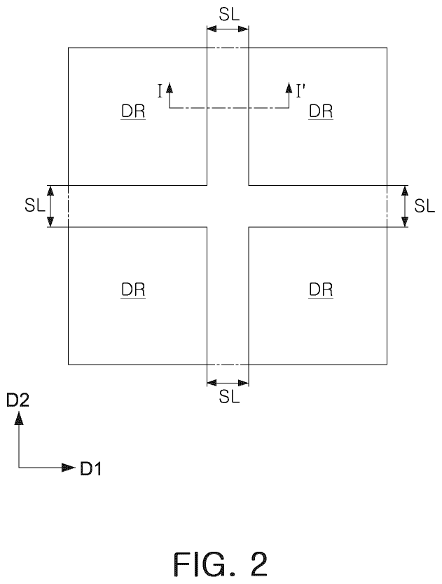

FIG. 1 is a plan view of a semiconductor substrate including a semiconductor device according to an example embodiment. FIG. 2 is a partially enlarged view of FIG. 1.

Referring to FIGS. 1 and 2, a semiconductor substrate W may include device regions DR and a scribe line region SL between the device regions DR. The scribe line regions SL may extend in a first horizontal direction D1 and in a second horizontal direction D2, intersecting the first horizontal direction D1. The device regions DR may be spaced apart from each other in the first horizontal direction D1 and the second horizontal direction D2, and may be surrounded by the scribe line region SL. A semiconductor device 100 may be formed by separating a device region DR along the scribe line region SL by a dicing process, which will be described below.

In an example embodiment, a volatile memory device such as a dynamic random access memory (DRAM) or a static random access memory (SRAM), or a non-volatile memory device such as a phase-change random access memory (PRAM), a magnetoresistive random access memory (MRAM), a ferroelectric random access memory (FeRAM), or a resistive random access memory (RRAM) may be provided in the device region DR. In an example embodiment, a logic device such as a microprocessor, an analog device, or a digital signal processor may be provided in the device region DR.

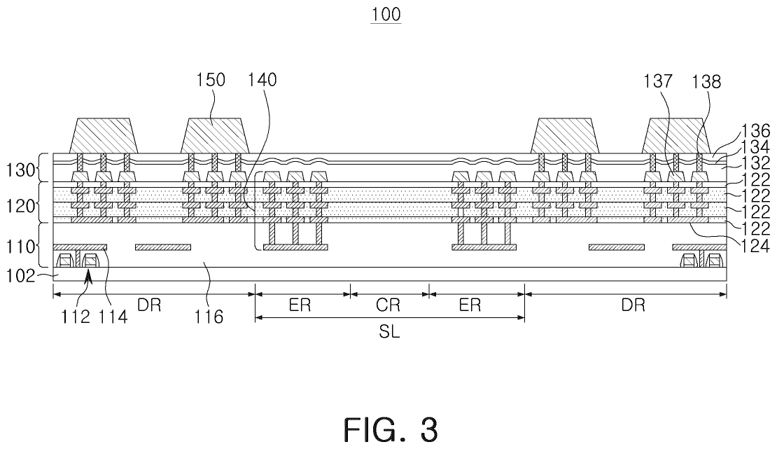

FIGS. 3 to 11 are vertical cross-sectional views along the line I-I′ of FIG. 2 of a semiconductor substrate illustrating a process sequence of a method of manufacturing a semiconductor device 100 according to an embodiment.

Referring to FIG. 3, a device layer 110, an interconnection layer 120, and an insulating structure 130 may be formed on a semiconductor substrate 102. The semiconductor substrate 102 may correspond to the semiconductor substrate W illustrated in FIG. 1.

The semiconductor substrate 102 may include device regions DR and a scribe line region SL between the device regions DR. The scribe line region SL may include edge regions ER and a cutting region CR between the edge regions ER. An edge region ER may surround a device region DR. The cutting region CR may refer to a portion to be separated during a dicing process to be described later. The semiconductor substrate 102 may include a semiconductor material. For example, the semiconductor substrate 102 may be a silicon substrate, a germanium substrate, a silicon germanium substrate, or a silicon-on-insulator (SOI) substrate. The semiconductor substrate 102 may include a semiconductor material such as a group IV semiconductor, a group III-V compound semiconductor, or a group II-VI compound semiconductor.

The device layer 110 may include integrated circuit devices 112, internal interconnections 114, and a lower interlayer insulating layer 116. The integrated circuit devices 112 may include a memory cell array including switching elements and data storage elements, and logic elements including an MOSFET, a capacitor, and a resistor. An internal interconnection 114 may be disposed on the integrated circuit devices 112, and may be electrically connected to at least one of the integrated circuit devices 112. The integrated circuit devices 112 may be disposed in the device region DR. The internal interconnection 114 may be disposed in the device region DR and the edge region ER. In some example embodiments, the internal interconnection 114 may also be disposed in the cutting region CR. The lower interlayer insulating layer 116 may cover the semiconductor substrate 102, the integrated circuit devices 112, and the internal interconnections 114. The internal interconnections 114 may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the internal interconnections 114 may include copper (Cu). The lower interlayer insulating layer 116 may include silicon oxide, silicon nitride, silicon oxynitride, or combinations thereof. For example, the lower interlayer insulating layer 116 may include silicon oxide.

The interconnection layer 120 may be formed on the device layer 110. The interconnection layer 120 may include lower insulating layers 122 and lower interconnections 124. The lower insulating layers 122 may be sequentially deposited on the lower interlayer insulating layer 116. The lower interconnections 124 may be disposed in the device region DR, and may be buried in the lower insulating layers 122. Although not specifically shown in FIGS. 3 to 11, at least one of the lower interconnections 124 may be electrically connected to the integrated circuit device 112. The lower interconnections 124 may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the lower interconnections 124 may include copper (Cu).

The lower insulating layer 122 may include a low-κ material having a low dielectric constant. For example, the lower insulating layer 122 may include silicon oxide doped with impurities or an organic polymer. In an example embodiment, the lower insulating layer 122 may include SiOCH, SiCN, or combinations thereof. Among the lower insulating layers 122, an uppermost lower insulating layer 122 may include a material, different from a material of a lower insulating layer 122 therebelow. For example, the uppermost lower insulating layer 122 may include silicon oxide.

The insulating structure 130 may be formed on the interconnection layer 120. The insulating structure 130 may include a first upper insulating layer 132, a second upper insulating layer 134, and a third upper insulating layer 136, and a lower conductive pattern 137 and a conductive via 138 may be formed in the insulating structure 130. In an example embodiment, a portion of the second upper insulating layer 134 overlapping the lower conductive pattern 137 in a vertical direction may protrude in an upward direction. The second upper insulating layer 134 may include a material having etch selectivity with respect to the first upper insulating layer 132. For example, the first upper insulating layer 132 may include a high density plasma (HDP) oxide. The second upper insulating layer 134 may include silicon nitride, silicon oxynitride, silicon carbonitride, or combinations thereof. In an example embodiment, the third upper insulating layer 136 may include silicon oxide. For example, the third upper insulating layer 136 may include tetraethyl orthosilicate (TEOS).

The lower conductive pattern 137 may be prepared by forming a conductive material on the interconnection layer 120 and then patterning the conductive material. The lower conductive pattern 137 may constitute an interconnection extending in a horizontal direction, and a pad connected to the interconnection. The lower conductive pattern 137 may be covered by the first upper insulating layer 132. The lower conductive patterns 137 may be located in the device region DR and the edge region ER, and at least one of the lower conductive patterns 137 may be electrically connected to the lower interconnection 124. The lower conductive pattern 137 may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the lower conductive pattern 137 may include aluminum (Al).

The conductive via 138 may vertically pass through the second upper insulating layer 134 and the third upper insulating layer 136, and may be connected to the lower conductive pattern 137. The lower conductive pattern 137 may include copper (Cu), aluminum (Al), tungsten (W), nickel (Ni), titanium (Ti), titanium nitride (TiN), tantalum (Ta), tantalum nitride (TaN), gold (Au), or combinations thereof. For example, the conductive via 138 may include tungsten (W).

In addition, a guard ring 140 may be formed in the edge region ER. The guard ring 140 may extend in a horizontal direction, to surround the device region DR. The guard ring 140 may include the internal interconnection 114, and the lower interconnection 124 provided as a plurality of layers, and the lower conductive pattern 137. In cross-sectional view, the guard ring 140 may pass through the interconnection layer 120. The guard ring 140 may mitigate or prevent occurrence of cracks in the semiconductor device 100.

An upper conductive pattern 150 may be formed on the insulating structure 130. The upper conductive pattern 150 may be prepared by forming a conductive material on the insulating structure 130 and then patterning the conductive material. In an example embodiment, the upper conductive pattern 150 may be formed by a separate process from the conductive via 138, and may be formed to be thicker than the conductive via 138. For example, a vertical thickness of the upper conductive pattern 150 may be thicker than a horizontal thickness (e.g., width) of the conductive via 138. Because the upper conductive pattern 150 may be formed to be thicker than the conductive via 138, resistance of the upper conductive pattern 150 may be reduced, and RC delay of the semiconductor device 100 may be reduced.

The upper conductive pattern 150 may constitute an interconnection extending in a horizontal direction, and a pad connected to the interconnection. The upper conductive pattern 150 may include, for example, a ground pad, a power pad, an AC pad, a data pad, and a DC pad. The ground pad may be a pad for providing a reference potential for circuit operation of the semiconductor device 100. The power pad may be a pad for supplying power for circuit operation. The AC pad may be a pad for supplying AC power to the semiconductor device 100 or receiving a signal for performing an AC test. The data pad may be a pad for input/output of a logic signal or data. The DC pad may be a pad for measuring a potential level at a specific location of the semiconductor device 100.

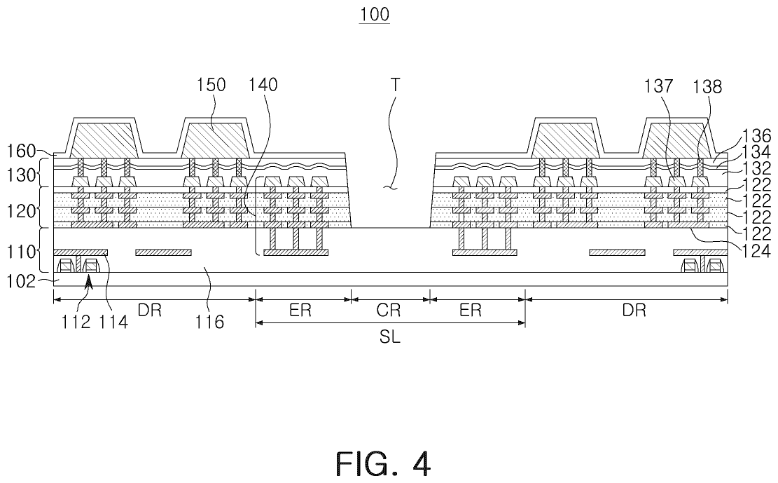

Referring to FIG. 4, a protective layer 160 covering the insulating structure 130 and the upper conductive pattern 150 may be formed. The protective layer 160 may be conformally formed along the insulating structure 130 and the upper conductive pattern 150. The protective layer 160 may include a material, equal to a material of the third upper insulating layer 136, and may include, for example, TEOS. In an example embodiment, a boundary between the protective layer 160 and the third upper insulating layer 136 may not be identified, and the protective layer 160 may be integrally connected to the third upper insulating layer 136.

After the protective layer 160 is formed, an upper surface (e.g., a portion of an upper surface in the cutting region CR) of the device layer 110 may be exposed by separating the interconnection layer 120, the insulating structure 130, and the protective layer 160. A side surface of the interconnection layer 120, a side surface of the insulating structure 130, and a side surface of the protective layer 160, and the upper surface of the device layer 110 may define a trench T. The trench T may extend in a horizontal direction to surround the device region DR and the edge region ER. In some example embodiments, the trench T may not completely cut the interconnection layer 120.

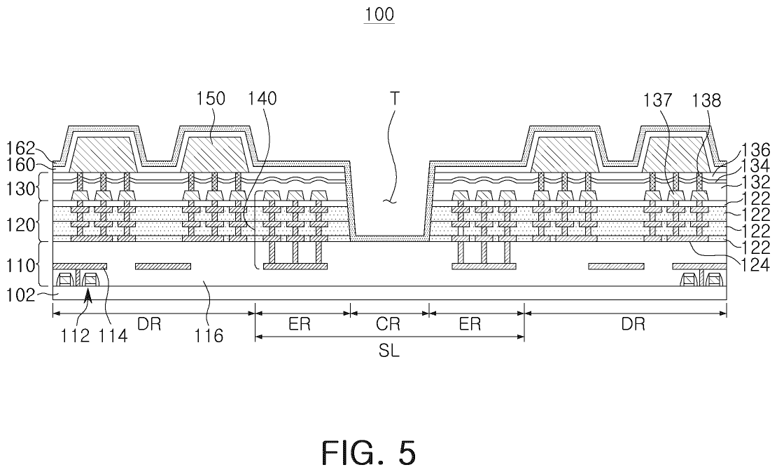

Referring to FIG. 5, an etch stop layer 162 covering the protective layer 160 and the trench T may be formed. The etch stop layer 162 may be conformally formed along the protective layer 160 and the trench T, and may cover at least a portion of the side surface of the interconnection layer 120, at least a portion of the side surface of the insulating structure 130, and at least a portion of the side surface of the protective layer 160. The etch stop layer 162 may include a first portion that vertically overlaps the upper conductive pattern 150, and a second portion that does not vertically overlap the upper conductive pattern 150. The first portion may be located on a higher level than the second part. In an example embodiment, the etch stop layer 162 may include silicon nitride.

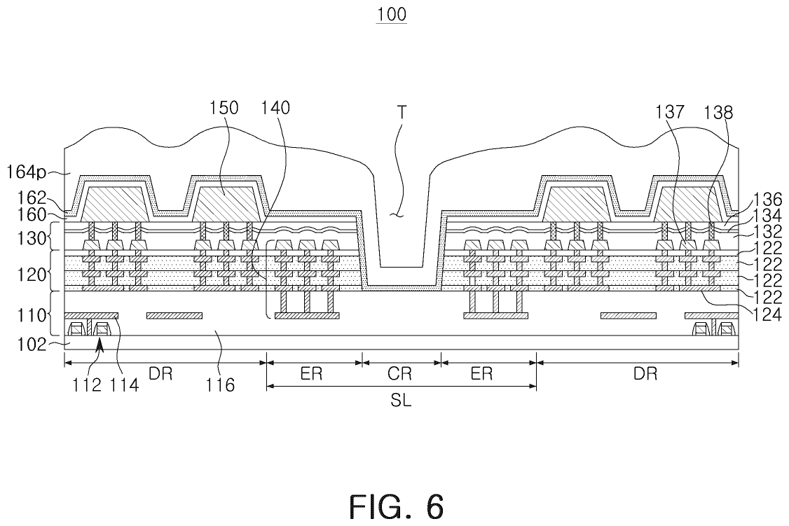

Referring to FIG. 6, an insulating material layer 164p covering the etch stop layer 162 may be formed. The insulating material layer 164p may fill a space between the upper conductive patterns 150, and may completely cover the upper conductive patterns 150. The insulating material layer 164p may include silicon oxide, and may include TEOS in an example embodiment. In an example embodiment, an upper surface of the insulating material layer 164p may not be flat, and for example, a portion corresponding to the upper conductive pattern 150 may protrude.

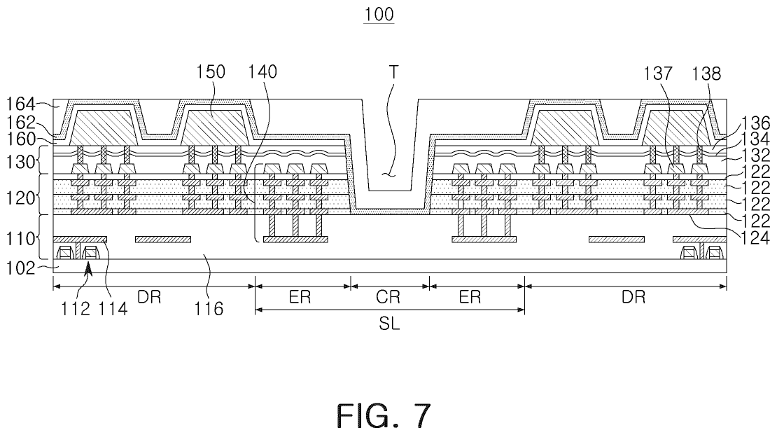

Referring to FIG. 7, a planarization process may be performed, and a first passivation layer 164 may be formed by removing (e.g., etching) the insulating material layer 164p. The planarization process may include a chemical mechanical polishing (CMP) process. For example, the CMP process may start from an upper portion of the insulating material layer 164p, and the insulating material layer 164p may be removed (e.g., etched) to reach the etch stop layer 162. In an example embodiment, an upper surface of the first passivation layer 164 may be coplanar with an upper surface of the etch stop layer 162. In other words, an upper surface of the first passivation layer 164 may be on a same plane with an upper end (e.g., an uppermost portion of the upper surface) of the etch stop layer 162. the first passivation layer 164 may be on portions of the etch stop layer 162 that are provided between the upper conductive patterns 150. As illustrated in FIG. 7, because the planarization process may be performed using the etch stop layer 162 as a stop layer, the first passivation layer 164 may be formed to have a constant height in the device region DR, and distribution thereof may be reduced.

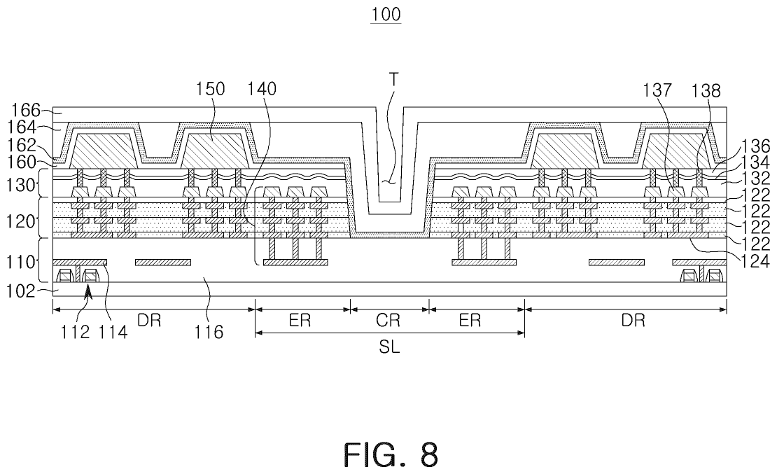

Referring to FIG. 8, a second passivation layer 166 may be formed on the etch stop layer 162 and the first passivation layer 164. The second passivation layer 166 may be conformally formed along the etch stop layer 162, the first passivation layer 164, and the trench T. The second passivation layer 166 may include silicon oxide, and may include, for example, TEOS. The second passivation layer 166 may be a layer for adjusting a thickness of the semiconductor device 100, and a thickness of the second passivation layer 166 may be changed according to example embodiments. In some example embodiments, the second passivation layer 166 may be omitted.

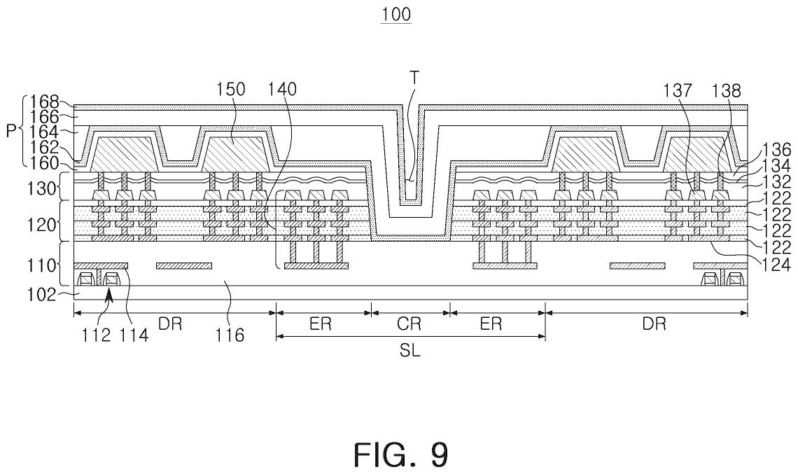

Referring to FIG. 9, an upper passivation layer 168 may be formed on the second passivation layer 166. The upper passivation layer 168 may be conformally formed along the second passivation layer 166 and the trench T. The protective layer 160, the etch stop layer 162, the first passivation layer 164, the second passivation layer 166, and the upper passivation layer 168 may form a passivation structure P. The passivation structure P may cover an inner wall of the trench T formed along the cutting region CR. The upper passivation layer 168 may include silicon nitride, silicon oxynitride, silicon carbonitride, or combinations thereof. For example, the upper passivation layer 168 may include silicon nitride.

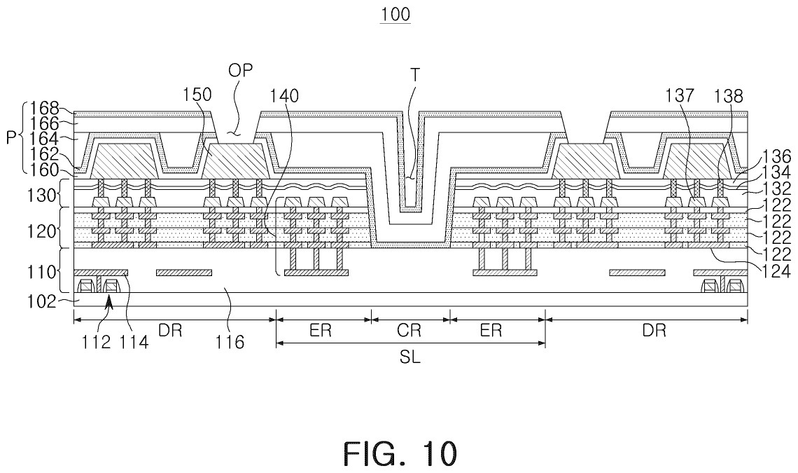

Referring to FIG. 10, an opening OP may be formed by partially etching the protective layer 160, the etch stop layer 162, the second passivation layer 166, and the upper passivation layer 168. At least one of the upper conductive patterns 150 may be exposed through the opening OP.

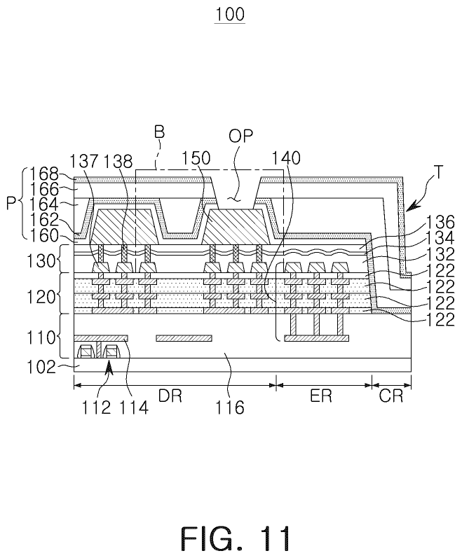

Referring to FIG. 11, a semiconductor device 100 may be prepared by separating the semiconductor substrate 102, the lower interlayer insulating layer 116, the etch stop layer 162, the first passivation layer 164, the second passivation layer 166, and the upper protective layer 168 by a dicing process. In some example embodiments, a laser beam may be irradiated to a rear surface of the semiconductor substrate 102. For example, a thin tape (not illustrated) may be attached to the semiconductor substrate 102, and a laser beam may be irradiated to a portion of the semiconductor substrate 102 in the cutting region CR. Physical properties of the semiconductor substrate 102 may be changed at a laser spot to which the laser beam is irradiated, and for example, physical strength of the semiconductor substrate 102 may be weakened. The semiconductor substrate 102 may be separated along the cutting region CR by extending the thin tape attached to the semiconductor substrate 102 in a horizontal direction. Alternatively, in some example embodiments, the dicing process may be a process of cutting the semiconductor substrate 102 using a sawing wheel.

As illustrated in FIGS. 6 and 7, because the planarization process may be performed to reach the etch stop layer 162, the first passivation layer 164 may be formed to have a thin thickness. Therefore, a thickness of the semiconductor device 100 may be reduced, and thermal resistance of the semiconductor device 100 may be reduced.

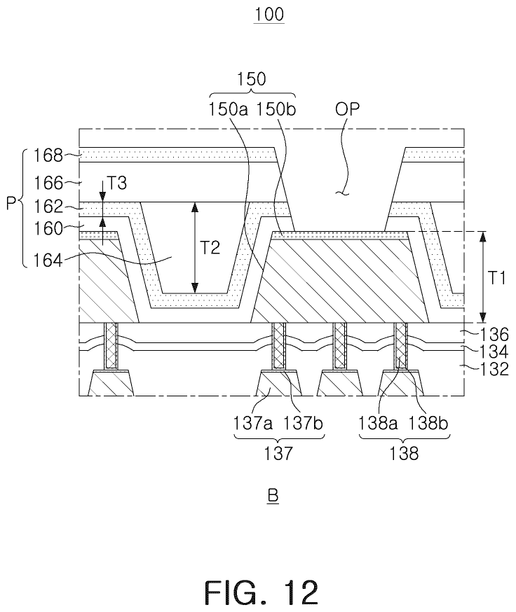

FIG. 12 is a partially enlarged view of the semiconductor device of FIG. 11. FIG. 12 may correspond to portion “B” of FIG. 11.

Referring to FIG. 12, in an example embodiment, the lower conductive pattern 137 may include a metal layer 137a and an anti-reflection layer 137b on the metal layer 137a. The metal layer 137a may include a conductive material, and may include, for example, aluminum (Al). The anti-reflection layer 137b may be formed to protect the lower conductive pattern 137 during a process of etching the second upper insulating layer 134 and the third upper insulating layer 136 to form the conductive via 138. The anti-reflection layer 137b may include at least one of titanium (Ti), tantalum (Ta), tantalum nitride (TaN), titanium nitride (TiN), titanium silicon nitride (TiSiN), tungsten (W), tungsten nitride (WN), tungsten carbide (WC), or tungsten carbonitride (WCN). For example, the anti-reflection layer 137b may include titanium nitride (TiN).

In an example embodiment, the conductive via 138 may include a metal layer 138a and a barrier layer 138b covering side and lower surfaces of the metal layer 138a. The metal layer 138a may include a conductive material, and may include, for example, tungsten (W). The barrier layer 138b may include a metal nitride, such as tantalum nitride (TaN), titanium nitride (TiN), or tungsten nitride (WN), and may include, for example, titanium nitride (TiN).

In an example embodiment, the upper conductive pattern 150 may include a metal layer 150a and an anti-reflection layer 150b covering an upper surface of the metal layer 150a. The anti-reflection layer 150b may be formed to protect the upper conductive pattern 150 during a process of etching the protective layer 160 and the etch stop layer 162 to form the opening OP. The metal layer 150a may include a conductive material, and may include, for example, aluminum (Al). The anti-reflection layer 150b may include at least one of titanium (Ti), tantalum (Ta), tantalum nitride (TaN), titanium nitride (TiN), titanium silicon nitride (TiSiN), tungsten (W), tungsten nitride (WN), tungsten carbide (WC), or tungsten carbonitride (WCN). For example, the anti-reflection layer 150b may include titanium nitride (TiN).

In an example embodiment, a vertical thickness T1 of the upper conductive pattern 150 may be about 1 μm to about 4 μm. A vertical thickness T2 of the first passivation layer 164 may be about 1.5 μm to about 3 μm. A thickness T3 of the etch stop layer 162 may be greater than 0 μm and less than or equal to about 0.1 μm. A thickness of the upper passivation layer 168 may be about 0.3 μm to about 0.6 μm.

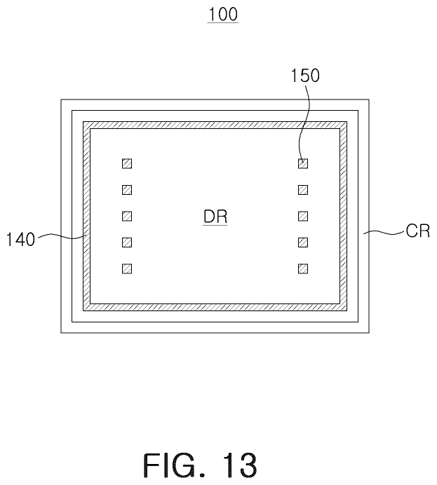

FIG. 13 is a plan view of a semiconductor device according to an example embodiment

Referring to FIG. 13, a guard ring 140 disposed in an edge region ER may extend in a horizontal direction, to surround a device region DR. In a plan view, the guard ring 140 is illustrated to have a rectangular shape, but is not limited thereto. In some example embodiments, the guard ring 140 may have a circular shape or an elliptical shape. A cutting region CR may be disposed outside of the guard ring 140, and may surround the guard ring 140. A trench T may extend in a horizontal direction along the cutting region CR.

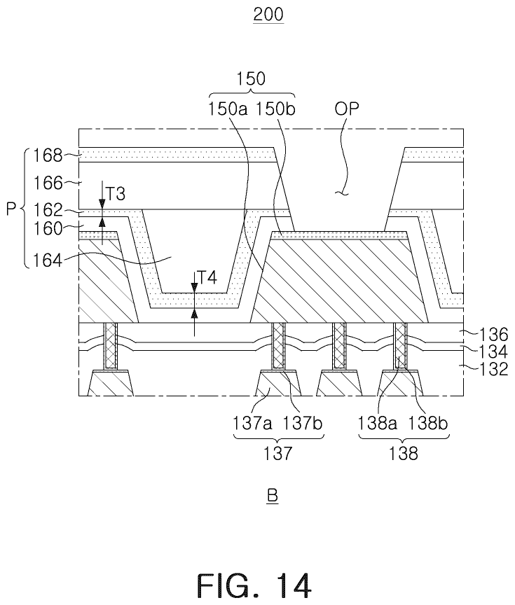

FIGS. 14 to 18 are vertical cross-sectional views of a semiconductor device according to some example embodiments.

Referring to FIG. 14, a semiconductor device 200 may include a passivation structure P covering an upper conductive pattern 150. In an example embodiment, a thickness of an etch stop layer 162 may not be constant. For example, the etch stop layer 162 may include a first portion vertically overlapping upper conductive patterns 150, and a second portion disposed between the upper conductive patterns 150 and not vertically overlapping the upper conductive patterns 150. The second portion may vertically overlap a first passivation layer 164. The first portion of the etch stop layer 162 may be partially removed by the planarization process described with reference to FIG. 7, and a thickness T3 of the first portion may be thinner than a thickness T4 of the second portion.

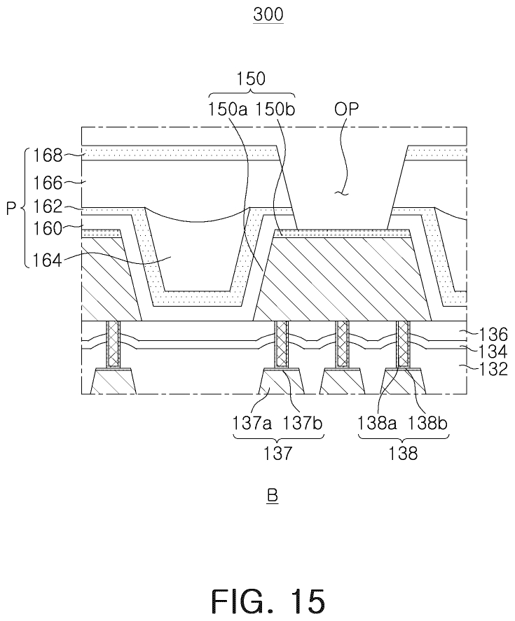

Referring to FIG. 15, a semiconductor device 300 may include a passivation structure P covering an upper conductive pattern 150. In an example embodiment, during the planarization process described with reference to FIG. 7, because a first passivation layer 164 may be over-polished by dishing, dishing may occur. For example, an upper surface of the first passivation layer 164 may be a concave curved surface, and at least a portion of the upper surface of the first passivation layer 164 may be located on a lower level than an upper surface of an etch stop layer 162.

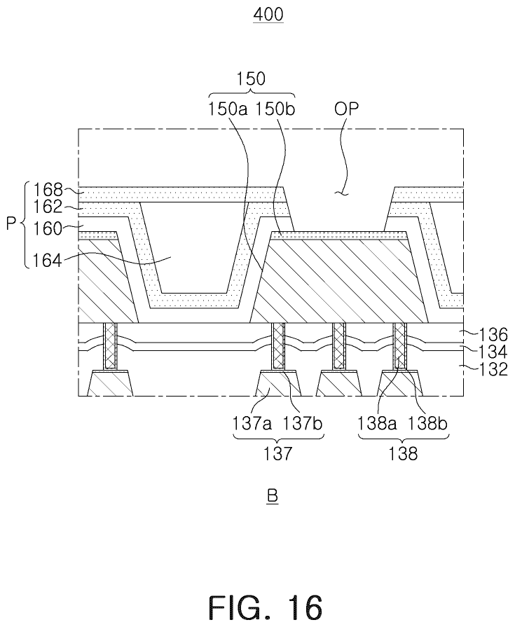

Referring to FIG. 16, a semiconductor device 400 may include a passivation structure P covering an upper conductive pattern 150. In an example embodiment, a second passivation layer 166 may be omitted. For example, an upper passivation layer 168 may be in contact with an upper end of an etch stop layer 162 and an upper surface of a first passivation layer 164. As noted above, the etch stop layer 162 may include the same material as the upper passivation layer 168, and thus a boundary between the etch stop layer 162 and the upper passivation layer 168 may not be identified. The first passivation layer 164 may be surrounded by the etch stop layer 162 and the upper passivation layer 168. For example, a lower surface and a side surface of the first passivation layer 164 may be in contact with the etch stop layer 162, and the upper surface of the first passivation layer 164 may be in contact with the upper passivation layer 168.

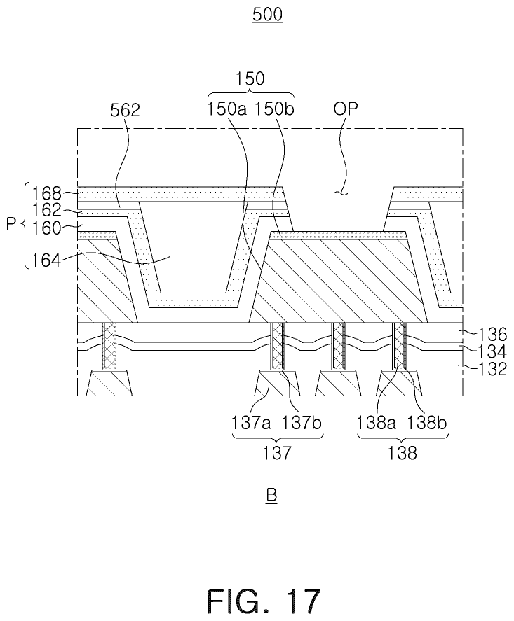

Referring to FIG. 17, a semiconductor device 500 may include a passivation structure P covering an upper conductive pattern 150. In an example embodiment, the passivation structure P may further include an oxide layer 562 between an etch stop layer 162 and an upper passivation layer 168. The oxide layer 562 may be formed by oxidizing a portion of the etch stop layer 162, and may include silicon oxynitride. The oxide layer 562 may be surrounded by the etch stop layer 162, a first passivation layer 164, and the upper passivation layer 168.

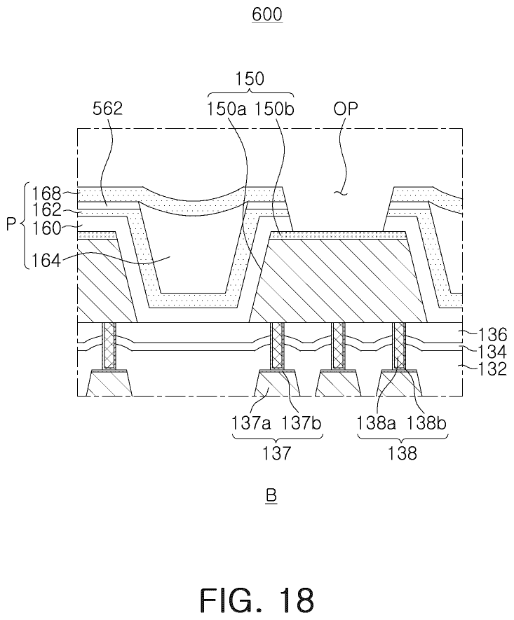

Referring to FIG. 18, a semiconductor device 600 may include a passivation structure P covering an upper conductive pattern 150. In an example embodiment, an upper surface of a first passivation layer 164 may be a concave curved surface, and at least a portion of the upper surface of the first passivation layer 164 may be located on a lower level than an upper end of an etch stop layer 162. An upper passivation layer 168 may cover the first passivation layer 164, and an upper surface of the upper passivation layer 168 may include a concave curved surface. For example, a portion of an upper surface of the upper passivation layer 168 vertically overlapping the first passivation layer 164 may be a curved surface.

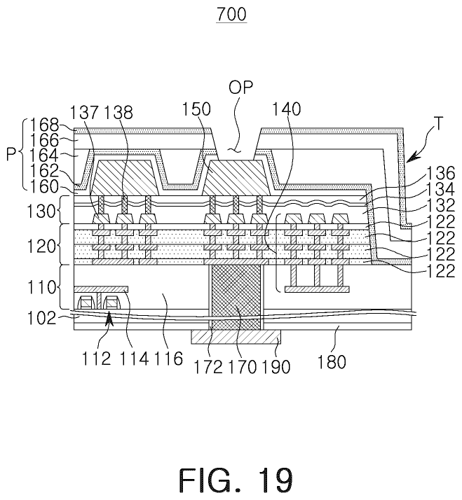

FIG. 19 is a vertical cross-sectional view of a semiconductor device according to an example embodiment.

Referring to FIG. 19, a semiconductor device 700 may further include a through-electrode 170, a via insulating layer 172, a lower passivation layer 180, and a via pad 190. The through-electrode 170 may vertically pass through a semiconductor substrate 102 and a device layer 110, and may be connected to an interconnection layer 120. The via insulating layer 172 may cover a side surface of the through-electrode 170. The through-electrode 170 may include copper (Cu), aluminum (Al), tungsten (W), nickel (Ni), titanium (Ti), titanium nitride (TiN), tantalum (Ta), tantalum nitride (TaN), gold (Au), or combinations thereof. The via insulating layer 172 may include an insulating material such as silicon oxide.

The lower passivation layer 180 may cover a lower surface of the semiconductor substrate 102, and the through-electrode 170 may pass through the lower passivation layer 180. The via pad 190 may be disposed on a lower surface of the lower passivation layer 180, and may be connected to the through-electrode 170. The via pad 190 may be electrically connected to the interconnection layer 120 through the through-electrode 170. In some example embodiments, the via pad 190 may overlap the lower passivation layer 180 in a horizontal direction (e.g., the via pad 190 may be embedded in the lower passivation layer 180) such that a side surface of the via pad 190 may be in contact with the lower passivation layer 180.

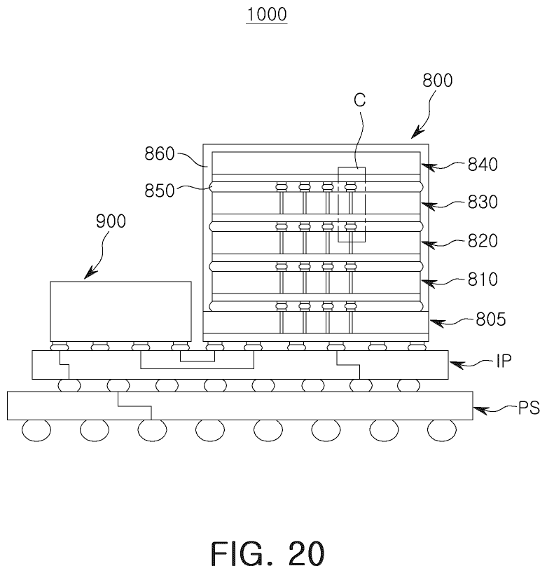

FIG. 20 is a vertical cross-sectional view of a semiconductor package including a semiconductor device according to some example embodiments.

Referring to FIG. 20, a semiconductor package 1000 of the present inventive concepts may be a high bandwidth memory (HBM) package. The semiconductor package 1000 may include a package substrate PS, an interposer IP mounted on the package substrate PS, and a memory package 800 and a processor chip 900, mounted on the interposer IP. The interposer IP may electrically connect the memory package 800 and the processor chip 900.

The memory package 800 may include a buffer chip 805, a first semiconductor device 810, a second semiconductor device 820, a third semiconductor device 830, and a fourth semiconductor device 840, sequentially stacked. The buffer chip 805 and the first to fourth semiconductor devices 810, 820, 830, and 840 may have structures identical to or similar to those of the semiconductor device 100 described with reference to FIGS. 11 and 12, and may include, for example, components corresponding to an etch stop layer 162 and a first passivation layer 164. In addition, the second to fourth semiconductor devices 820, 830, and 840 may include structures corresponding to a through-electrode 170, a via insulating layer 172, a lower passivation layer 180, and a via pad 190.

In an example embodiment, the buffer chip 805 may be a different type of semiconductor chip from the first to fourth semiconductor devices 810, 820, 830, and 840. For example, the buffer chip 805 may be a logic chip, and the first to fourth semiconductor devices 810, 820, 830, and 840 may be memory chips. The logic chip may include a microprocessor, an analog device, or a digital signal processor. The memory chips may include a volatile memory chip such as a dynamic random access memory (DRAM) or a static random access memory (SRAM), or a non-volatile memory chip such as a phase-change random access memory (PRAM), a magnetoresistive random access memory (MRAM), a ferroelectric random access memory (FeRAM), or a resistive random access memory (RRAM).

The memory package 800 may further include an adhesive layer 850 and an encapsulant 860. The adhesive layer 850 may be disposed between the buffer chip 805 and the first semiconductor device 810 and between the first to fourth semiconductor devices 810, 820, 830, and 840. The adhesive layer 850 may be a non-conductive film (NCF) or a non-conductive paste (NCP). The encapsulant 860 may be a resin including epoxy, polyimide, or the like. For example, the resin may include a bisphenol-group epoxy resin, a polycyclic aromatic epoxy resin, an o-cresol novolac epoxy resin, a biphenyl epoxy resin, or a naphthalene-group epoxy resin.

The processor chip 900 may be a central processing unit (CPU), a graphic processing unit (GPU), a mobile application, or a digital signal processor (DSP) chip.

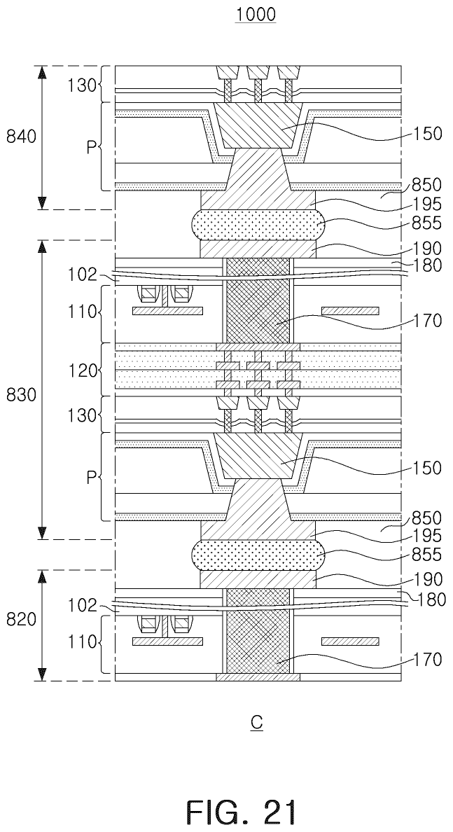

FIG. 21 is a partially enlarged view of the semiconductor package of FIG. 20. FIG. 21 may correspond to portion “C” of FIG. 20.

Referring to FIG. 21, the memory package 800 may further include a bump 855 between the second semiconductor device 820 and the third semiconductor device 830 and between the third semiconductor device 830 and the fourth semiconductor device 840. The first to fourth semiconductor devices 810, 820, 830, and 840 may further include a connection pad 195 connected to an upper conductive pattern 150. The connection pad 195 may be in contact with the upper conductive pattern 150 while filling the opening OP illustrated in FIG. 19. The connection pad 195 may pass through a protective layer 160, the etch stop layer 162, and an upper passivation layer 168, and may be in contact with side surfaces thereof. The bump 855 may connect the via pad 190 and the connection pad 195 between adjacent semiconductor devices 820, 830, and 840. The adhesive layer 850 may cover a side surface of the via pad 190, a side surface of the connection pad 195, and a side surface of the bump 855. In an example embodiment, the bump 855 may be omitted, and the via pad 190 and the connection pad 195 may be in direct contact with each other.

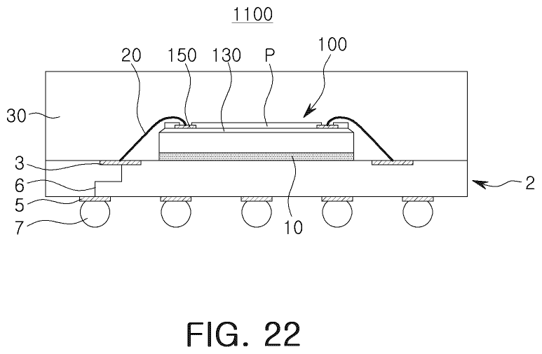

FIG. 22 is a vertical cross-sectional view of a semiconductor package including a semiconductor device according to some example embodiments.

Referring to FIG. 22, a semiconductor package 1100 may include a substrate 2, an adhesive member 10, a bonding wire 20, and an encapsulant 30. The semiconductor package 1100 may also include a semiconductor device 100 on the substrate 2.

The substrate 2 may include upper pads 3, lower pads 5, an internal interconnection 6, and an external connection terminal 7. In an example embodiment, the substrate 2 may be a printed circuit board, and may include an insulating material such as a phenolic resin, an epoxy resin, a prepreg, or the like. In another example embodiment, the substrate 2 may be a redistribution layer in which an insulating material and a conductive material are stacked. The upper pads 3 and the lower pads 5 may be prepared by forming a metal layer on a base of the substrate 2 and then patterning the metal layer.

The upper pads 3 may be disposed on an upper surface of the substrate 2, and may be electrically connected to the semiconductor device 100. The lower pads 5 may be disposed on a lower surface of the substrate 2, and the upper pads 3 may be electrically connected to a lower pad 5 corresponding thereto through the internal interconnection 6. The external connection terminal 7 may be disposed below the lower pads 5. A lower pad 5, an upper pad 3, and an interconnection may include a metal such as copper (Cu). The external connection terminal 7 may be a solder bump 855.

The semiconductor device 100 may include an insulating structure 130, an upper conductive pattern 150, and a passivation structure P, identical to or similar to the components of the semiconductor device 100 illustrated in FIG. 11. The insulating structure 130 may be disposed on the semiconductor device 100. The passivation structure P may be disposed on the insulating structure 130, and may protect the insulating structure 130 from external physical impact. The upper conductive pattern 150 may be buried in the passivation structure P. The upper conductive pattern 150 may be connected to the upper pad 3 by the bonding wire 20.

The adhesive member 10 may be disposed between the substrate 2 and the semiconductor device 100. The adhesive member 10 may fix the semiconductor device 100 on the substrate 2. The adhesive member 10 may be a die attach film (DAF), but is not limited thereto. The encapsulant 30 may cover the substrate 2, the semiconductor device 100, and the bonding wire 20.

According to some example embodiments, an etch stop layer may be formed on an upper conductive pattern. Because a planarization process may be performed using the etch stop layer as a stop layer, a protective layer covering the upper conductive pattern may have a constant thickness and may be formed to have a thin thickness. Therefore, thermal resistance of a semiconductor device therefrom may be reduced.

Various advantages and effects of the present inventive concepts are not limited to the above, and will be easily understood by one of ordinary skill in the art while appreciating the disclosed example embodiments.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
an insulating structure on a semiconductor substrate;
lower conductive patterns in the insulating structure;
upper conductive patterns on the insulating structure;
conductive vias in the insulating structure and connecting at least one of the upper conductive patterns to at least one of the lower conductive patterns;
a protective layer covering the insulating structure and the upper conductive patterns;
an etch stop layer covering the protective layer;
a first passivation layer between the upper conductive patterns and on the etch stop layer; and
an upper passivation layer on the first passivation layer.

2. The semiconductor device of claim 1, wherein an upper surface of the first passivation layer is coplanar with an upper end of the etch stop layer.

3. The semiconductor device of claim 1, further comprising:
a second passivation layer between the etch stop layer and the upper passivation layer,
wherein the first passivation layer is surrounded by the etch stop layer and the second passivation layer.

4. The semiconductor device of claim 1, wherein the etch stop layer has a first thickness and a second thickness, thicker than the first thickness.

5. The semiconductor device of claim 4, wherein the etch stop layer comprises a first portion vertically overlapping the upper conductive patterns, and a second portion vertically overlapping the first passivation layer,
wherein the first portion has the first thickness, and the second portion has the second thickness.

6. The semiconductor device of claim 1, wherein
an upper surface of the first passivation layer comprises a curved surface,
at least a portion of the upper surface of the first passivation layer is on a lower level than an upper end of the etch stop layer.

7. The semiconductor device of claim 1, wherein the upper passivation layer is in contact with an upper surface of the first passivation layer.

8. The semiconductor device of claim 7, further comprising:
an oxide layer between the etch stop layer and the upper passivation layer.

9. The semiconductor device of claim 7, wherein
the upper surface of the first passivation layer comprises a curved surface, and
an upper surface of a portion of the upper passivation layer vertically overlapping the first passivation layer is a curved surface.

10. The semiconductor device of claim 1, wherein a thickness of each of the upper conductive patterns is 1 μm to 4 μm.

11. The semiconductor device of claim 1, wherein a thickness of the first passivation layer is 1.5 μm to 3 μm.

12. The semiconductor device of claim 1, wherein a thickness of the etch stop layer is 0.1 μm or less.

13. The semiconductor device of claim 1, further comprising:
a via pad below the semiconductor substrate, and
a through-electrode connected to the via pad and passing through the semiconductor substrate.

14. The semiconductor device of claim 1, wherein
the semiconductor substrate comprises an element region, an edge region surrounding the element region, and a cutting region surrounding the edge region, and
the etch stop layer extends to the edge region and the cutting region and covers a side surface of the insulating structure.

15. The semiconductor device of claim 1, wherein the etch stop layer comprises a material different from a material of the protective layer and a material of the first passivation layer.

16. A semiconductor package comprising:
a plurality of semiconductor devices sequentially stacked on a buffer chip;
an adhesive layer between the plurality of semiconductor devices; and
an encapsulant covering the buffer chip and the plurality of semiconductor devices,
wherein one or more of the semiconductor devices includes,
a semiconductor substrate,
an insulating structure on an upper surface of the semiconductor substrate,
a via pad on a lower surface of the semiconductor substrate,
a through-electrode connected to the via pad and passing through the semiconductor substrate,
upper conductive patterns on the insulating structure,
a protective layer covering the insulating structure and the upper conductive patterns,
an etch stop layer covering the protective layer,
a first passivation layer between the upper conductive patterns and on the etch stop layer,
an upper passivation layer on the first passivation layer, and
a connection pad connected to one of the upper conductive patterns.

17. The semiconductor package of claim 16, wherein the connection pad passes through the protective layer, the etch stop layer, and the upper passivation layer.

18. A semiconductor device comprising:
a semiconductor substrate including a device region, an edge region surrounding the device region, and a cutting region surrounding the edge region;
an insulating structure on the semiconductor substrate, the insulating structure including a first upper insulating layer, a second upper insulating layer, and a third upper insulating layer that are sequentially stacked;
lower conductive patterns in the first upper insulating layer;
a first upper conductive pattern and a second upper conductive pattern on the insulating structure;
conductive vias passing through the second upper insulating layer and the third upper insulating layer, the conductive vias connecting the first upper conductive pattern to at least one of the lower conductive patterns; and
a passivation structure on the insulating structure, the first upper conductive pattern, and the second upper conductive pattern, the passivation structure including an opening exposing the first upper conductive pattern,
wherein the passivation structure includes,
a protective layer covering the first upper conductive pattern and the second upper conductive pattern,
an etch stop layer covering the protective layer,
a first passivation layer between the first upper conductive pattern and the second upper conductive pattern and on the etch stop layer,
a second passivation layer covering the etch stop layer and the first passivation layer, and
an upper passivation layer on the second passivation layer.

19. The semiconductor device of claim 18, wherein
the etch stop layer defines a trench along the cutting region and is in contact with a side surface of the insulating structure and a side surface of the protective layer.

20. The semiconductor device of claim 18, wherein
a lower surface of the first passivation layer is on a higher level than a lower surface of the first upper conductive pattern, and
an upper surface of the first passivation layer is on a higher level than an upper surface of the first upper conductive pattern.
